(19) United States
(12) Patent Application Publication
(10) Pub. No.: US 2021/0280785 A1
(43) Pub. Date: Sep. 9, 2021

(54) ORGANIC VAPOR JET DEPOSITION DEVICE CONFIGURATION

(71) Applicant: Universal Display Corporation, Ewing, NJ (US)

(72) Inventors: Xin XU, Plainsboro, NJ (US); Gregory MCGRAW, Yardley, PA (US); William E. QUINN, Whitehouse Station, NJ (US)

(21) Appl. No.: 16/331,615

(22) PCT Filed: Oct. 18, 2017
(86) PCT No.: PCT/US2017/057219

§ 371 Date: Mar. 8, 2019

Related U.S. Application Data
(60) Provisional application No. 62/409,466, filed on Oct. 18, 2016.

(51) Int. Cl. H01L 51/00; C23C 14/22; C23C 14/12; C23C 14/24

(52) U.S. Cl. CPC H01L 51/0005; H01L 51/001; C23C 14/24; C23C 14/12; C23C 14/228

(57) ABSTRACT

Devices and techniques are provided for depositing material on a substrate, such as for fabrication of OLEDs and layers used in OLEDs. A depositor block includes one or more delivery apertures, one or more exhaust apertures, and one or more confinement gas channels. Each delivery aperture is arranged such that it is between an exhaust aperture and a confinement gas channel, thereby improving deposition by reducing overspray of material.

### CROSS-REFERENCE TO RELATED APPLICATIONS

This application is a non-provisional of, and claims the priority benefit of U.S. Provisional Patent Application Ser. No. 62/409,466, filed Oct. 18, 2016, the entire contents of which are incorporated herein by reference.

### FIELD

The present invention relates to arrangements for depositing materials such for use as emitters in organic light emitting diodes, and devices, such as organic light emitting diodes, including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is provided. The OLED can include an anode, a cathode, and an organic layer, disposed between the anode and the cathode. According to yet another embodiment, the organic light emitting device is incorporated into one or more device selected from a consumer product, an electronic component module, and/or a lighting panel.

According to an embodiment, a device is provided that includes a depositor including a first delivery aperture in fluid communication with a delivery channel that is connectable to a source of material to be deposited on a substrate, a first exhaust aperture in fluid communication with a first exhaust channel, and a first confinement gas channel, where the first delivery aperture is disposed between the first exhaust channel and the first confinement gas channel. The first exhaust aperture and the first confinement gas channel may be positioned relative to one another to cause a flow of material from the first delivery aperture to the first exhaust channel when the material to be deposited on the substrate is ejected from the first delivery aperture toward the substrate. The first exhaust channel may include a fluid path between a source of low pressure and a region under the depositor block. The first confinement gas channel may include or be formed from a region between the depositor block and the substrate. The depositor block also may include a second delivery aperture, disposed at least partially between the first delivery aperture and the second delivery aperture. The device may include a second confinement gas channel that includes or is formed by a region between the depositor block and the substrate. The first delivery aperture, the second delivery aperture, and the exhaust aperture may be disposed between the first confinement gas channel and the second confinement gas channel. Alternately, the depositor block may include the first confinement gas channel enclosed within it that is in communication with an external source of confinement gas, and a first confinement gas aperture that is in plane with the delivery and exhaust apertures in fluid communication with the first confinement gas channel. The first delivery aperture is disposed between the first confinement gas aperture and the first exhaust aperture. The depositor block may further include a second delivery aperture and a second confinement gas aperture, where the first delivery aperture, the second delivery aperture, and the exhaust aperture may be disposed between the first confinement gas aperture and the second confinement gas aperture. Each of the first confinement gas channel and the second confinement gas channel may include or be formed by a fluid path between a region under the depositor block and a source of pressure higher than the pressure in the region under the depositor block. The first confinement gas channel may include or be formed by a fluid path between a region under the depositor block and a source of pressure higher than the pressure in the region under the depositor block. The delivery aperture may include a single aperture in the depositor block, or it may include multiple openings in the depositor block. The delivery channel may be disposed at an angle relative to the exhaust channel. During operation of the device, the flow of material may include carrier gas and material to be deposited on the substrate that did not adsorb to the substrate after being ejected from the deposition toward the substrate.

In an embodiment, a method of operating a device disclosed herein is provided that includes ejecting material to be deposited on a substrate from a first delivery aperture, through a deposition zone between the delivery aperture and the substrate, toward the substrate; providing a first flow of confinement gas via a first confinement gas channel to the deposition zone; and removing material from the deposition zone via a first exhaust channel, wherein the material removed from the deposition zone comprises carrier gas and material to be deposited on the substrate that was not adsorbed onto the substrate after being ejected toward the substrate. The first delivery aperture may be disposed between a source of the confinement gas and the exhaust channel. The first confinement gas channel may include or be formed by a region between the delivery aperture and the substrate. The method further may include ejecting material to be deposited on the substrate from a second delivery aperture toward the substrate, wherein the exhaust aperture is disposed at least partially between the first delivery aperture and the second delivery aperture. A second confinement gas flow may be provided via a second confinement gas channel that comprises a region between the first delivery aperture and the substrate. The first delivery aperture, the second delivery aperture, and the exhaust aperture may be disposed between the first confinement gas channel and the second confinement gas channel. The first confinement gas channel may include or be formed by a fluid path between a region under the delivery aperture and a source of pressure higher than the pressure in the region under the delivery aperture. Alternately, the first confinement gas channel in communication with an external source of confinement gas may be enclosed within the depositor block such that a first confinement gas aperture that is in plane with the delivery and exhaust apertures in fluid communication with the first confinement gas channel.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows overspray effects in a conventional deposition system.

FIG. 4 shows a schematic representation of an EDC exhaust-delivery-confinement printing structure according to an embodiment.

FIG. 5 shows a simulation of flow streamlines for an arrangement as shown in FIG. 4 according to an embodiment.

FIG. 6 shows another EDC depositor arrangement as viewed from below a depositor block according to an embodiment.

FIG. 7 shows simulated thickness profiles for relatively low rates of exhaust flow according to an embodiment.

FIG. 8 shows simulated thickness profiles for 9 sccm and 18 sccm according to an embodiment.

FIG. 9 shows a simulated feature profile under process conditions designed to produce a 120 μm feature width according to an embodiment.

FIG. 10 shows a cross-sectional view of an arrangement including angled deposition channels according to an embodiment.

FIG. 11 shows examples of features printed with 9 and 18 sccm of argon confinement gas according to an embodiment.

FIG. 12 shows deposition rates vs. FW5M for modeled cases according to embodiments disclosed herein.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

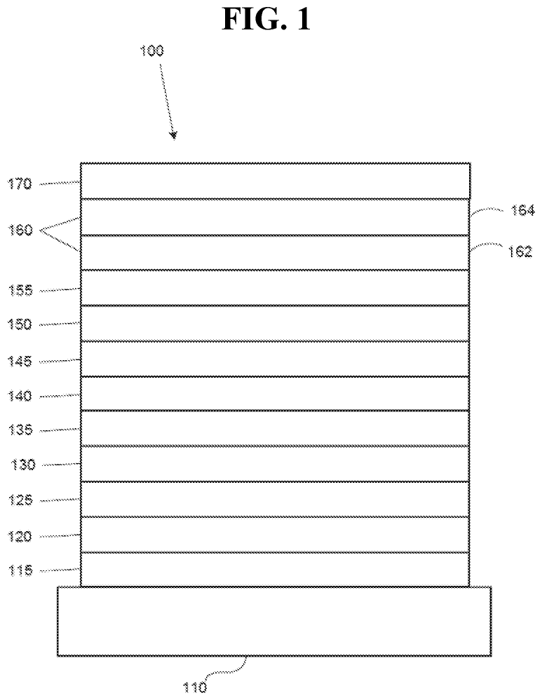

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

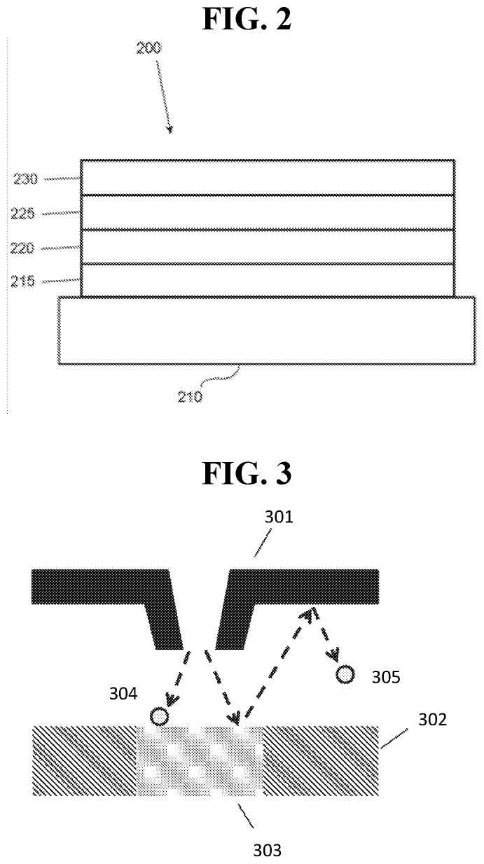

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

[Insert description of the OLED embodiment here.]

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

As previously disclosed, various layers of OLEDs and similar devices may be fabricated using OVJP, such as described in U.S. Pat. No. 7,431,968, and OVJP-type techniques. OVJP is a technique for depositing patterned arrays of organic thin films without the use of liquid solvents or shadow masks. An inert carrier gas transports organic vapor from evaporation sources to a nozzle array. The nozzle array generates a jet of gas-vapor mixture that impinges on a substrate. The organic vapor condenses on the substrate in a well-defined location. Features can be drawn by moving the substrate relative to the print head. Co-deposition of host and dopant, as required for PHOLEDs, may be achieved, for example, by mixing vapors from different sources upstream of the nozzle. Microfabricated nozzle arrays have been demonstrated to achieve printing resolution comparable to that required for display applications. However, deposition of organic material beyond the intended boundaries of a printed feature, or overspray, is a frequent problem of OVJP techniques. A variety of transport mechanisms may contribute to this problem by carrying dilute organic vapor away from the nozzle. This vapor has the potential to contaminate neighboring features.

For example, when the gas flow is dominated by intermolecular interactions, i.e. when the Knudsen number Kn is less than 1 (where Kn=λ/l where λ is the mean free path in the carrier gas field and l is the characteristic length of the depositor), the organic vapor plume emanating from the nozzle is broadened by both convection and diffusion. When Kn is greater than 1, printed features are broadened by ballistic motion of vapor molecules transverse to the substrate normal. In either case, feature broadening is exacerbated if organic molecules are not immobilized upon contact with the substrate.

A molecule of organic vapor that comes into contact with the substrate can either irreversibly adsorb to it or reflect away from it. Adsorbed material condenses to become part of a printed feature. Material that does not condense is scattered back into the surrounding gas ambient. A sticking coefficient α is defined as the probability that a molecule of organic vapor condenses per encounter with the substrate. A sticking coefficient a in the range of 0.8-0.9 is typical of OLED materials.

Convective and diffusive broadening can be reduced by operating OVJP processes at a very low background pressure, such as 10⁻⁴ Torr or less. Overspray persists, however, due to non-unity α as shown in FIG. 3. Printing fine features in a conventional OVJP system requires placing a heated nozzle array 301 close to the substrate. Organic molecules that fail to adsorb on the substrate 302 reflect back onto the underside of the nozzle array and become scattered beyond the deposition zone 303. Organic molecules that initially adsorb to the substrate 304 stay within the desired printing area, while molecules that do not adsorb 305 are scattered further afield. Organic molecules do not stick to the underside of the nozzle because it is heated and are redirected onto the substrate and land outside of the desired printing area. It is therefore desirable to rapidly remove material that does not adsorb to the substrate to prevent feature broadening.

For example, U.S. Patent Publication Nos. 2015/0380648 and 2015/0376787, the disclosure of each of which is incorporated by reference in its entirety, disclose OVJP arrangements that include a delivery channel, an exhaust channel and a confinement flow. For example, U.S. 2015/0380648 discloses a DEC-type configuration which has a delivery channel in the center with two exhaust channel in adjacent to delivery channel.

Disclosed herein are arrangements of gas flow apertures for an OVJP device, such as a microarray, in which a central exhaust aperture is surrounded by one or more delivery apertures injecting organic vapor laden carrier gas, which are in turn surrounded by one or more confinement apertures injecting carrier gas with no organic vapor. That is, in embodiments disclosed herein, a delivery aperture or channel that provides material to be deposited may be disposed between an exhaust channel or aperture and a confinement channel or aperture. In general, an exhaust aperture or channel removes undeposited material from a deposition region, and a confinement aperture or channel prevents undesirable spread of material ejected by a delivery aperture such as a nozzle. Such a configuration may be referred to as an Exhaust-Delivery-Confinement (EDC) configuration of a print head or similar device. It has been found that this configuration may greatly reduce the amount of organic material deposited beyond the intended boundaries of printed features. For example, confinement gas flows may be situated adjacent to two delivery channels so as to drive a net inflow into an exhaust aperture and thereby prevents organic material from re-depositing on the substrate outside the intended deposition zone.

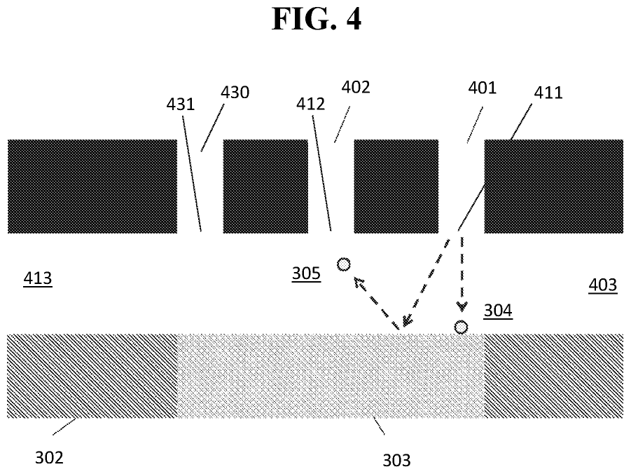

An example of an EDC exhaust-delivery-confinement printing structure is shown in cross section in FIG. 4. An inert carrier gas laden with organic vapor, referred to herein as a delivery gas, is injected into the deposition zone through a pair of delivery channels 401. Each of the exhaust channel 402 and the delivery channel 401 may be in fluid communication with an associated aperture 412, 411, respectively, in the deposition block. Another stream of inert gas, referred to as a confinement gas, may be fed inward from the edge of the deposition zone. The stream of confinement gas picks up surplus organic vapor as it moves from the confinement channel 403 to the exhaust channel 402. This net inflow prevents organic vapor from spreading beyond the deposition zone where printing is desired. As disclosed in further detail herein, each of the confinement flow and the exhaust flow may be provided via an aperture in a common deposition block with the delivery channel and aperture 401, or each may be provided from another channel, such as through a region 403 from outside the deposition zone between the deposition block and the substrate.

In general, each exhaust channel disclosed herein may connect the deposition zone between the depositor block and the substrate to a region of lower pressure. That is, the pressure in the deposition zone may be higher than a region with which the exhaust channel is in fluid communication, such as a vacuum source. Similarly, a confinement gas source may be provided from a region of relatively higher pressure than the pressure in the deposition zone.

As shown in FIG. 4, a confinement gas channel may be created when a depositor block is disposed near a substrate to deposit material on the substrate via the depositor block. The confinement gas channel may be, or include, the region between the depositor block and the substrate, as well as a fluid path from the deposition zone to a region outside the deposition zone. A confinement gas channel need not, though it may, include a bore or other channel through a portion of the depositor block.

Multiple delivery apertures and/or confinement gas flows may be used, for example in a CDEDC-type arrangement. For example, a second confinement channel 413 may include another region between the depositor block and the substrate. A second delivery aperture 431 may be in fluid communication with a second delivery channel 430, and disposed between the exhaust aperture 412 and the confinement channel 413. Thus, in a CDEDC configuration, an exhaust aperture 412 may be disposed between two delivery apertures 431, 411, and the exhaust and delivery apertures 411, 412, 431 may be disposed between confinement channels 413, 403. Each of the apertures 411, 412, 431 may be circular, square, rectangular, or any other suitable shape. In some embodiments, it may be preferred for the apertures to be rectangular and parallel or perpendicular to the direction of relative movement of the depositor block and the substrate.

A delivery aperture as disclosed herein and as shown in FIG. 4 may include a single opening in the depositor block, or it may include multiple openings that operate as a single aperture. For example, multiple materials may be deposited concurrently by using multiple delivery channels in the depositor block that lead to a common delivery channel or plenum. Similarly, multiple delivery apertures may be placed in relatively close proximity within the depositor block and thereby operate as a single “aperture” as disclosed herein. Specific examples of various aperture configurations that may be suitable for use in embodiments disclosed herein are provided in U.S. Publication Nos. 2015/0380648 and 2015/0376787.

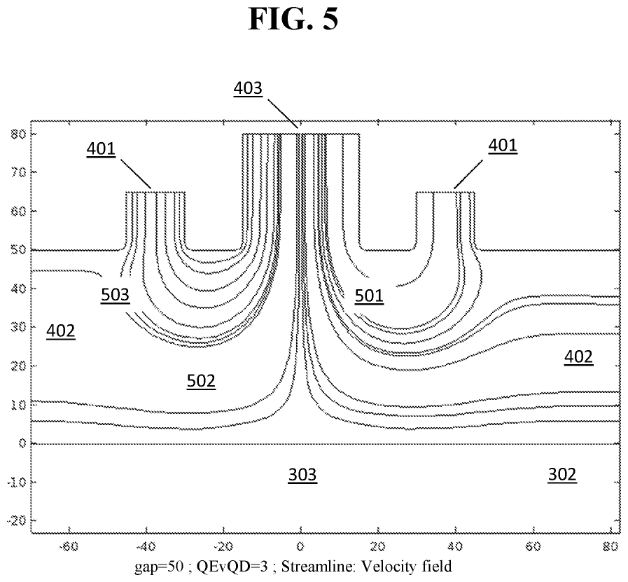

FIG. 5 shows a simulation of flow streamlines for an arrangement as shown in FIG. 4. The delivery flow 501 passes from the delivery channel to the exhaust aperture as previously disclosed. The confinement flow 502 passes from the confinement channel at the edge of the deposition zone to the exhaust aperture at the center of the deposition zone. The confinement flow creates a sheath around the delivery flow where the two regions of flow come into contact 503. Organic vapor within the delivery flow therefore must diffuse through the confinement flow to reach the substrate. Organic material that does not diffuse through the confinement flow and condense onto the substrate is removed by the exhaust flow.

In embodiments disclosed herein, the confinement gas may be provided either by a channel and aperture through a depositor block or other deposition device, or by another channel from the deposition zone between the depositor block and the substrate to a region of lower or higher pressure, respectively. For example, as previously disclosed, a confinement flow may be provided via an opening at the edge of the deposition zone. For example, a confinement gas flow may be provided from outside the deposition zone, flowing inward toward the deposition zone and ultimately through the deposition zone, exiting via an exhaust aperture and/or channel.

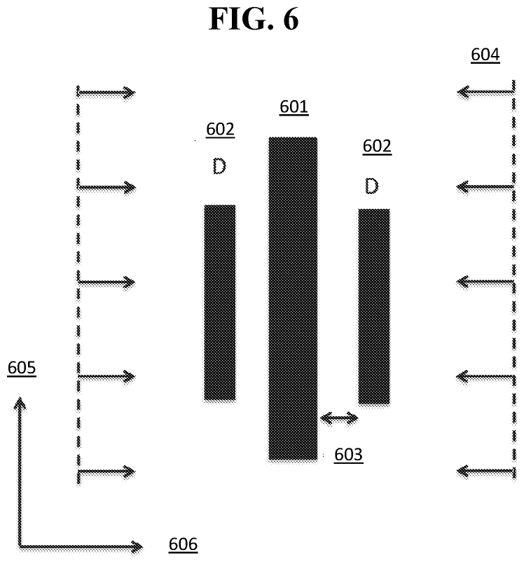

FIG. 6 shows another EDC depositor arrangement as viewed from below a depositor block. The arrangement includes an exhaust aperture 601 in the block, which is surrounded by two delivery apertures 602. A confinement flow 604 is provided from outside the deposition zone between the depositor block and the substrate, flowing inward toward the exhaust aperture 601.

A depositor of the arrangement shown in FIG. 6 was simulated using COMSOL Multiphysics computational fluid dynamics software. The depositor is viewed in plane from the perspective of the substrate. The simulated structure includes a central exhaust aperture 601 of 400 μm by 30 μm, surrounded by delivery apertures 602 of 300 μm by 15 μm. Each aperture leads to a corresponding channel through the depositor. For example, the exhaust aperture 601 is in fluid communication with an exhaust channel through the depositor. The exhaust channel may be connected to and in fluid communication with an external source of relatively low pressure, i.e., a region having a pressure lower than the pressure in the deposition zone between the depositor and the substrate. The low-pressure zone may be a vacuum source. Spacers 603 of 15 μm thickness separate the delivery and exhaust apertures.

A confinement gas may be provided from the sides of the deposition zone 604 as previously disclosed. Accordingly, each delivery aperture may be described as being disposed “between” a confinement gas channel and the exhaust aperture 601 or an exhaust channel to which the exhaust aperture is connected. Alternatively or in addition, the confinement gas may be provided by way of one or more confinement gas apertures disposed toward the outer edge of the depositor relative to the delivery apertures, i.e., such that each delivery aperture 602 would be disposed between the central exhaust aperture 601 and a confinement gas aperture.

Features are printed along a direction parallel to the long axis of the aperture 605, so that the widths along the short axis 606 define the size of printed features. The fly height separating the underside of the depositor from the top of the substrate was simulated to be 50 μm. The delivery apertures were simulated to produce a constant molar flux of organic vapor in all cases, so the reported deposition rates are proportional to the fraction of organic material that deposits on the substrate. Deposition rate and material usage efficiency are therefore equivalent.

Both the delivery and confinement gasses were assumed to be helium. Delivery gas flow was 6 sccm per aperture pair, while the exhaust flow was variable. Pressure in the deposition zone was 200 Torr. The print head is at 600K, while the substrate is 293K. The path of organic vapor through the depositor was calculated by solving the convection-diffusion equation for a dilute component in a gas solution. The diffusivity of the organic vapor was calculated using the kinetic theory of gasses, assuming typical values of 500 g/mole for molecular mass and 1 nm for molecular diameter for the organic molecules.

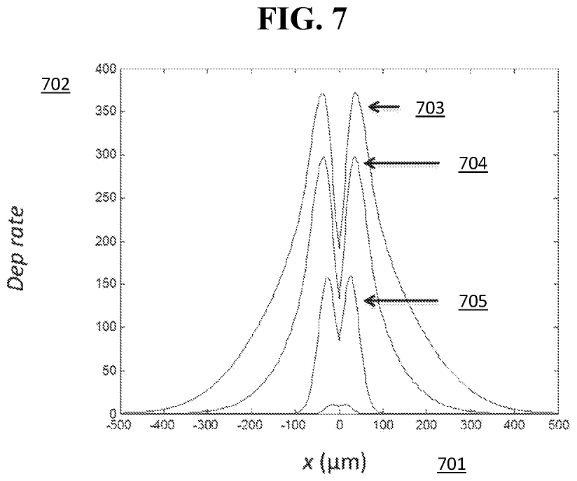

The resulting thickness profiles of features printed under these conditions are shown in FIGS. 7-9. The results for low rates of exhaust flow are shown in FIG. 7. The x axis 701 shows the distance in microns from the centerline of the exhaust channel along the in-plane direction perpendicular to substrate motion, while they axis 702 is proportional to the rate of organic vapor deposition at that distance from the centerline. Deposition rates are expressed in arbitrary units, since calculating an exact deposition rate would require additional assumptions about organic vapor source design and material properties. The lowest exhaust flow rate 703, 4.5 sccm, is sufficiently low that there is a net outflow of gas from the deposition zone. Because the exhaust is unable to remove all delivery gas, organic deposition onto the substrate is very rapid. A very wide deposition profile results, with a full width to 5% of maximum (FW5M) of 654 μm. Profiles wider than 120 μm are generally unacceptable for display printing applications. Feature size can be reduced, albeit at the expense of deposition rate, by increasing the exhaust flow rate. As the exhaust flow increases to 6 sccm as shown at 704, the FW5M decreases to 434 μm. The deposition rate, which is proportional to the curve height of each thickness profile, decreases as well. A FW5M of 158 μm is achieved at a 9 sccm exhaust flow, as shown at 705.

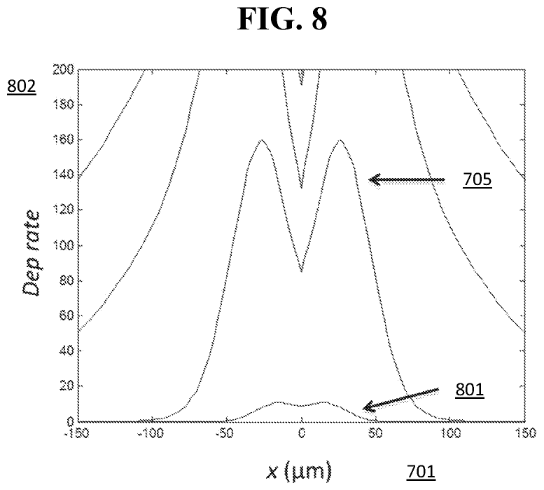

Higher exhaust flows may be used to achieve a narrower deposition profile, and thereby meet the desired width of 120 μm which is generally considered suitable for display applications. FIG. 8 shows the 9 sccm and the 18 sccm case at 801. The vertical axis 802 has a much finer scale than in FIG. 7 due to the relatively low deposition rate. As shown a feature having a 101 μm FW5M can be achieved at 18 sccm exhaust flow, albeit at a very low deposition rate.

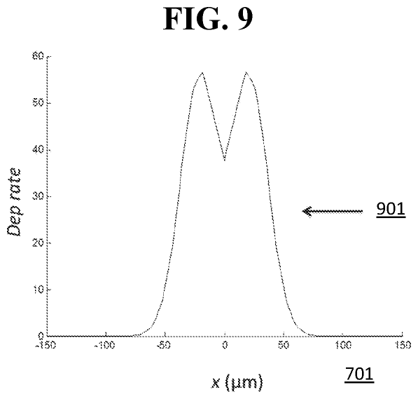

FIG. 9 shows the expected feature profile 901 under process conditions designed to meet the 120 μm specification. It has an exhaust flow of 12 sccm and a FW5M of 119 μm. The average deposition rates over the printing area are 5.04 units at 4.5 sccm, 2.79 units at 6 sccm, 0.748 units at 9 sccm, 0.212 units at 12 sccm, and 0.035 units at 18 sccm of exhaust.

In some embodiments, one or more delivery channels may be positioned at an angle relative to an exhaust channel. For example, referring to FIG. 6, the exhaust aperture 601 may be in fluid communication with an exhaust channel that extends into the deposition block in a direction normal to the substrate, at least in the region closest to the exhaust aperture 601. The delivery apertures 602 may be in fluid communication with delivery channels that are arranged at an angle relative to the exhaust channel, i.e., such that each delivery channel is farther away from the exhaust channel at increasing distances into the deposition block.

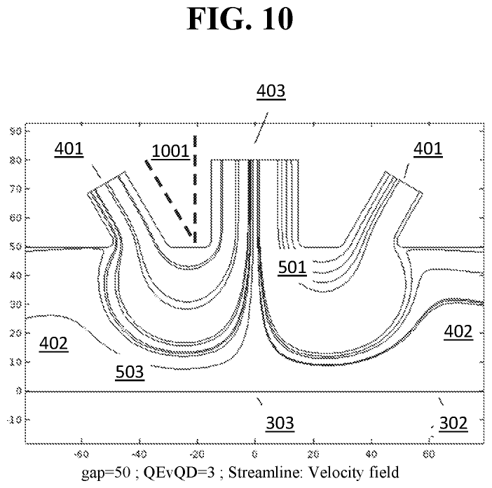

FIG. 10 shows a cross-sectional view of such an arrangement with modeled gas flows. The delivery channels were angled relative to the exhaust aperture at an angle 1001 of 30°. The relative angle imparts the delivery gas stream with inward momentum relative to the central exhaust. As a result, the printed features tend to be slightly narrower than if the delivery channels are not angled. In the 9 sccm case with helium confinement gas, the FW5M is reduced to 144.95 μm, a change of −8.2%. The increase in resolution comes at the expense of a decrease in deposition rate because the inward momentum also results in more organic vapor in the delivery stream being captured by the exhaust before it can reach the substrate. The expected deposition rate, therefore, decreases by 26.74%. Angled delivery channels therefore appear to create a penalty in deposition rate and utilization efficiency while only providing a modest improvement in the resolution of printed features. However, such a tradeoff may be desirable or acceptable for applications in which a narrower deposition profile is desired but a higher deposition rate is not required.

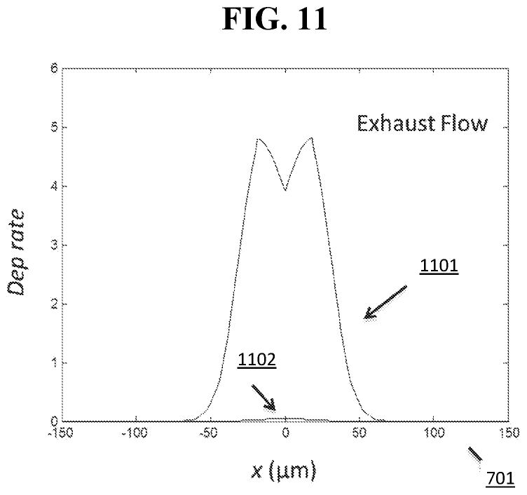

Because organic vapor must cross the confinement flow to be deposited on the substrate, a confinement gas that permits diffusion of organic vapor is used. For example, helium may be used, although it may permit organic vapor to diffuse in the plane of the substrate as well as normal to the substrate, thereby widening features. Diffusion of organic vapor through the confinement flow can be suppressed by replacing helium with argon. FIG. 11 shows examples of features printed with 9 and 18 sccm of argon confinement gas. A FW5M of 102 μm is achieved at 9 sccm, as shown at 1101, with a deposition rate under these conditions of 0.016 units. Features of comparable width can be achieved with helium confinement flow at 18 sccm. However, the associated deposition rate is with helium confinement gas is 0.035 units, more than twice as fast. This suggests that, while higher resolution printing can be achieved at a given exhaust flow rate if argon is used as a confinement gas instead of helium, features of a given resolution can be printed more rapidly if helium confinement gas is used. At a flow of 18 sccm, the argon confinement flow decreases deposition to such a degree that relatively little material reaches the substrate, as shown at 1102.

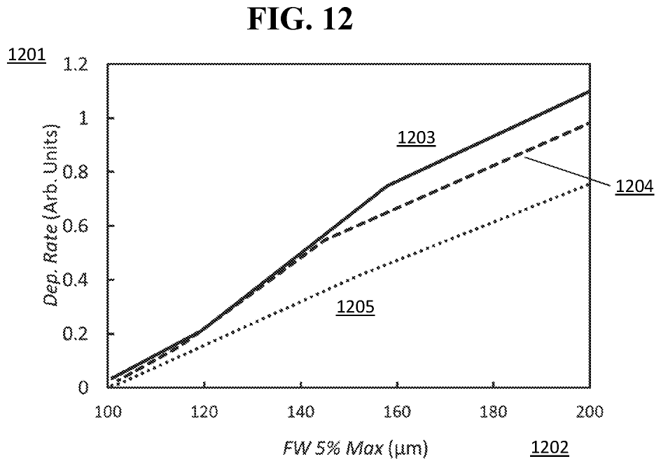

It was found that a basic tradeoff exists between printing resolution and deposition rate for all of the studied cases. This is summarized in FIG. 12, which shows the deposition rate 1201 vs. FW5M 1202 for each of the modeled cases. For features from 100-200 μm in width, the differences in performance between the straight exhaust channel (solid) 1203 and angled exhaust channel (dashed) 1204 depositors is relatively modest, with straight channels providing a slight advantage in deposition rate. Both cases, however, are superior to a straight channel case that uses Argon as a confinement gas (dotted) 1205. Therefore, of the example arrangements simulated, it was found that a straight channeled depositor using helium as a confinement gas provides the most rapid and efficient deposition for printed features of a given resolution. However, various other arrangements and combinations may be used without departing from the scope of the invention as disclosed herein.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria are satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

We claim:

1. A device comprising:
a depositor block comprising:
a first delivery aperture in fluid communication with a delivery channel that is connectable to a source of material to be deposited on a substrate; and
a first exhaust aperture in fluid communication with a first exhaust channel;
a first confinement gas channel;
wherein the first delivery aperture is disposed between the first exhaust channel and the first confinement gas channel; and
wherein the first exhaust aperture and the first confinement gas channel are positioned relative to one another to cause a flow of material from the first delivery aperture to the first exhaust channel when the material to be deposited on the substrate is ejected from the first delivery aperture toward the substrate.

2. The device of claim 1, wherein the first exhaust channel comprises a fluid path between a source of low pressure and a region under the depositor block.

3. The device of claim 1, wherein the first confinement gas channel comprises a region between the depositor block and the substrate.

4. The device of claim 3, wherein the depositor block further comprises a second delivery aperture, and the exhaust aperture is disposed at least partially between the first delivery aperture and the second delivery aperture.

5. The device of claim 4, further comprising a second confinement gas channel that comprises a region between the depositor block and the substrate, wherein the first delivery aperture, the second delivery aperture, and the exhaust aperture are disposed between the first confinement gas channel and the second confinement gas channel.

6. The device of claim 1, wherein the depositor block comprises:
the first confinement gas channel; and
a first confinement gas aperture in fluid communication with the first confinement gas channel;
wherein the first delivery aperture is disposed between the first confinement gas aperture and the first exhaust aperture.

7. The device of claim 6, wherein the depositor block further comprises:
a second delivery aperture; and
a second confinement gas aperture;
wherein the first delivery aperture, the second delivery aperture, and the exhaust aperture are disposed between the first confinement gas aperture and the second confinement gas aperture.

8. The device of claim 7, wherein each of the first confinement gas channel and the second confinement gas channel comprises a fluid path between a region under the depositor block and a source of pressure higher than the pressure in the region under the depositor block.

9. The device of claim 1, wherein the first confinement gas channel comprises a fluid path between a region under the depositor block and a source of pressure higher than the pressure in the region under the depositor block.

10. The device of claim 1, wherein the delivery aperture comprises a single aperture in the depositor block.

11. The device of claim 1, wherein the delivery channel is disposed at an angle relative to the exhaust channel.

12. The device of claim 1, wherein the flow of material comprises carrier gas and material to be deposited on the substrate that did not adsorb to the substrate after being ejected from the deposition toward the substrate.

13. A method of depositing material on a substrate, the method comprising:
ejecting material to be deposited on a substrate from a first delivery aperture, through a deposition zone between the delivery aperture and the substrate, toward the substrate;
providing a first flow of confinement gas via a first confinement gas channel to the deposition zone; and
removing material from the deposition zone via a first exhaust channel, wherein the material removed from the deposition zone comprises carrier gas and material to be deposited on the substrate that was not adsorbed onto the substrate after being ejected toward the substrate;
wherein the first delivery aperture is disposed between a source of the confinement gas and the exhaust channel.

14. The method of claim 13, wherein the first confinement gas channel comprises a region between the delivery aperture and the substrate.

15. The method of claim 14, further comprising ejecting material to be deposited on the substrate from a second delivery aperture toward the substrate, wherein the exhaust aperture is disposed at least partially between the first delivery aperture and the second delivery aperture.

16. The method of claim 15, further comprising providing a second confinement gas flow via a second confinement gas channel that comprises a region between the first delivery aperture and the substrate, wherein the first delivery aperture, the second delivery aperture, and the exhaust aperture are disposed between the first confinement gas channel and the second confinement gas channel.

17. The method of claim 13, wherein the first confinement gas channel comprises a fluid path between a region under the delivery aperture and a source of pressure higher than the pressure in the region under the delivery aperture.
